(19) United States
(12) Patent Application Publication
(10) Pub. No.: US 2011/0241660 A1
(43) Pub. Date: Oct. 6, 2011

(54) THE DETECTION OF DEPOSITS COMPRISING AT LEAST ONE FERROMAGNETIC MATERIAL ON OR CLOSE TO THE EXTERNAL WALL OF A TUBE

(76) Inventor: Antoine Gemma, Marseille (FR)

(21) Appl. No.: 13/122,133

(22) PCT Filed: Oct. 5, 2009
(86) PCT No.: PCT/EP09/62907

§ 371 Date: Jun. 10, 2011

(30) Foreign Application Priority Data
Oct. 3, 2008 (FR) 0856708

(51) Int. Cl. G01R 33/12

(52) U.S. Cl. 324/220

(57) ABSTRACT

The present invention relates to a method for the detection of fouling or clogging deposits comprising at least one ferromagnetic material, such as nickel, magnetite or similar material, on or close to the external wall of a tube, characterized in that it comprises at least the following steps: a magnetized source is positioned inside the tube and immobilized heightwise therein; the source is rotated about itself by being driven by means of an electric motor; and the intensity of the current drawn by said electric motor during this rotational movement is measured and the curve obtained is analysed in order to detect, and where appropriate evaluate, the clogging.

### AREA OF THE INVENTION

This present invention concerns the general area of magnetic detection methods and devices, and more particularly the area of the methods and devices for the detection of fouling or clogging by deposits of ferromagnetic materials on or close to the cooling tubes of a steam generator in a pressurised water nuclear reactor or PWR.

### TECHNICAL BACKGROUND

In the area of nuclear electricity power plants of the Pressurised Water Reactor (PWR) type, it is well known that the heat produced in the core of the reactor is transmitted through a closed circuit known as the primary circuit in which water flows to a so-called secondary circuit in which the water which is converted into steam feeds the turbines for the production of electricity.

In reference to FIG. 1 which represents a steam generator in cut-away perspective, each nuclear electricity power plant of the PWR type generally has three or four steam generators, where each said steam generator is composed of a containment vessel (5) housing the primary circuit (10) and the secondary circuit (15). The thermal exchange between the primary circuit (10) and the secondary circuit (15) is done through a multiplicity of inverted U tubes (20). The said tubes are held in place by spacing plates that are stopped by tie-rods fixed in the bottom part of the steam generator.

In reference to FIG. 2, which represents a perspective view of a spacing plates (25) detail and of the tubes (20), the said spacing plates (25) include cross-shaped holes (30), known as quadrifoliate holes, through which the said cylindrical tubes (20) go through.

It is known that there is a clogging deposits (35) formation at quadrifoliate holes (25) level (FIG. 2) between the tubes (20) and the spacing plates (25). The consequence of these deposits (35) is firstly, in normal operation, to change the mechanical stresses on the tubes (4) and secondly, in the event of an incident or accident, to increase the forces on the spacing plates (25), thus increasing the risk that the tubes (20) will break.

Moreover, it is also known that so-called fouling deposits form on the external surface of the tubes (20), causing a reduction in the efficiency of the thermal exchange in the steam generator.

In order to eliminate these clogging or fouling deposits, it is very common to clean the tubes and the spacing plates using chemical cleaning methods. These methods consist of injecting chemical reagents into the secondary circuit of the steam generators in order to break down and dissolve these deposits of oxides such as magnetites.

However the quantity of reagents to be injected depends on the quantity of oxides present in the steam generators.

As a consequence, it is first necessary to determine the quantity of the oxides.

To this end, methods and devices for the detection of magnetite deposits, using a low-frequency axial, eddy-current probe, are well known, the said probe being inserted into the tubes of the steam generator, from which the measurements are correlated with televised images or on-line samples that are representative of the deposits encountered.

This method type has the drawback of requiring a time, for analysis of the data acquisitions, of about 1 month, thus very considerably affecting the costs. Moreover, the measurements obtained by this method has a low accuracy.

One is also aware of the method and the device for the detection of deposits described in American patent U.S. Pat. No. 4,088,946. The said device includes an eddy-current probe that is moved at constant speed in a tube, so as to detect deposits.

In the same manner as mentioned previously, this probe has poor accuracy and requires the acquisition of video images.

Other methods and devices for the detection of deposits on the outer wall of tubes that have the same drawbacks are also described in French patent application FR 2 459 490 and American patent U.S. Pat. No. 4,700,134.

### BRIEF DESCRIPTION OF THE INVENTION

One of the aims of the invention is therefore to overcome these drawbacks by proposing a method and a device for the detection of deposits that include at least one ferromagnetic material on or close to the outer wall of a tube, more particularly intended for the detection of deposits on or close to the tubes of a steam generator in a nuclear electricity power plant of the PWR type, of simple design and low cost, and with good accuracy as well as high reliability.

The applicant company has already proposed in its French patent application FR0853200 (not yet published at the date of this present application) a detection device, as illustrated in FIG. 3, that has a probe (105), such as one or more permanent magnets, as well as means (110) that include an electric motor (120), a gearbox (160) and a shaft (150) and that, by means of a system of nut and screw type, allow the probe to be moved inside the tube (115) using a given control system, at constant speed for example. The feed current to the motor varies depending on the thickness of the ferromagnetic deposits (nickel, magnetite or similar) (165) located on or close to the wall of the tube (115). Analysis of the variation of this current can therefore be used to detect the existence of fouling or clogging in the tube.

As can be understood easily, such a solution, although it enables one to detect the presence, and estimate the volume, of the deposits around the tube and in the tube/spacing-plate connection, does not allow one to detect which are the obstructed foliate passages and the depth at which the deposits are located at a spacing plate.

For its part, the new solution presented here allows one to overcome these drawbacks.

In particular, it proposes a method for the detection of fouling or clogging deposits that include at least one ferromagnetic material, such as nickel, magnetite or similar, on or close to the outer wall of a tube, characterised in that it includes at least the following stages:
positioning and locking in altitude of a magnetised source inside the tube,
rotation of the source on itself driving it with an electric motor and measuring the amplitude of the current in the said electric motor during this driving in rotation,
analysis of the curve obtained in order to detect and where appropriate to evaluate the clogging at the said spacer.

In this way, it is possible to be in possession of information on the distribution of deposits around the tube, and therefore to detect which are the obstructed foliate passages.

Advantageously, after rotation of the source, the latter is moved incrementally in altitude inside the tube and, after locking in position, the previous stages are repeated.

Thus all portions of the tube are covered, and in particular the spacing plates, over a certain depth.

The invention also proposes a device that embodies such a method.

### DRAWINGS

Other advantages and characteristics will emerge more clearly from the description that follows of several execution variants, given as non-restrictive examples, of the device for the detection of magnetic deposits on or close to a non-magnetic tube according to the invention, from the appended drawings in which:

FIG. 1, already discussed, is a cut-away perspective view of a steam generator in nuclear electricity power plants of the PWR type;

FIG. 2, already discussed, is a perspective view of a detail of the tubes going through the quadrifoliate holes of the spacing plates, where the said quadrifoliate holes have so-called clogging deposits;

FIG. 3, already discussed, is a schematic representation, in longitudinal section, of the detection device according to the invention inserted into a tube that has a fouling deposit;

FIG. 4 is a schematic representation in perspective illustrating a detection device according to one possible embodiment of the invention;

FIG. 5 is a block diagram illustrating the different stages for one possible embodiment of the invention;

FIGS. 6a and 6b respectively illustrate different possible positions of the permanent magnet in relation to the foliate passage tube, as well as the acquisition curve obtained by moving the said permanent magnet in relation to the different unobstructed foliate passages, with FIG. 6c illustrating three successive positions of the rotating magnetic probe in relation to the foliate passage of the tube represented in FIG. 6a;

FIGS. 7a to 7c correspond to FIGS. 6a to 6c, in the case in which four foliate passages are obstructed;

FIGS. 8a and 8b correspond to FIGS. 6a and 6b in the case in which three foliate passages are obstructed;

FIGS. 9a and 9b correspond to FIGS. 6a and 6b in the case in which two foliate passages are obstructed;

FIGS. 10a and 10b correspond to FIGS. 6a and 6b in the case in which one foliate passage is obstructed;

FIG. 11 illustrates the control cycle of a device of the type illustrated in FIG. 4;

FIG. 12 illustrates an example of acquisition curves obtained with such a device.

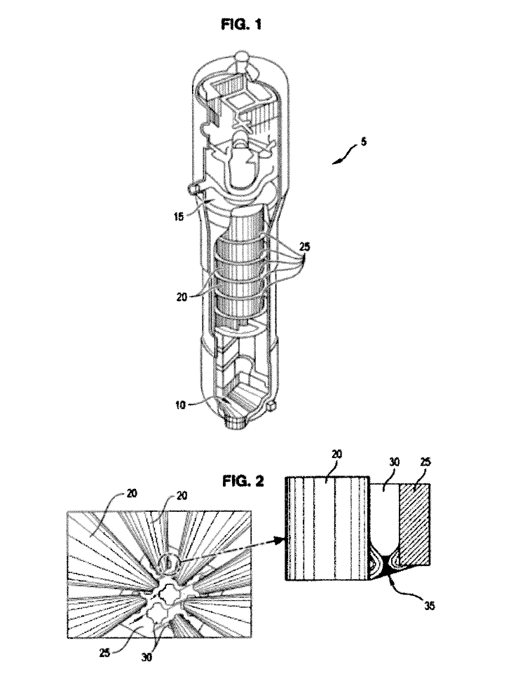

### DETAILED DESCRIPTION

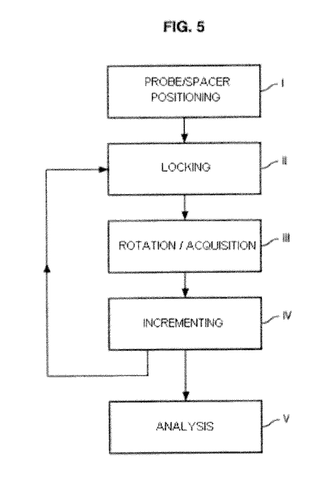

With reference to FIG. 4, a detection device (200), is represented that includes, in a tube (215), a magnetised source probe (205) which, for example, includes one or more permanent magnets as well as means (210) for the driving in rotation of the said source (205) in the said tube (215).

In the example described, the source (205) includes a single permanent magnet (206) supported by a mild-steel plate (207) itself mounted on a stainless steel support (208). The magnetic plane, PM, of the permanent magnet (206) has also been represented in the figure. This is radial in relation to the cylinder that constitutes the tube (215).

The said means (210) of driving in rotation are composed in particular of an electric gearbox (211). The electric motor of this motorised gearbox (211) is connected to a device (212) for measuring the feed current of the said motor, such as an ammeter for example, itself connected to a computer (213) of the PC type. An algorithm in the form of a program recorded on a physical support, such as the hard disk and/or the memory of the computer (213), stores and analyses curves of variations in the feed current or power of the electric motor in order to determine the obstructed foliate passages at the spacers, as well as the depths (altitudes) at which the deposits are located.

A propulsion shaft (300), or a system of the motorised gearbox and screw/nut type, also provide for the positioning of the probe at a given altitude in the latter. A locking system (301) is used, by clamping for example, to maintain the probe at this altitude while the motorised gearbox (211) drives it in rotation in the tube (215).

Such a structure is used in the manner illustrated in FIG. 5.

The probe is first positioned in altitude, at the height of the spacing plate (265) that one wishes to test (stage I).

The position of the probe in altitude in the tube is then locked using means 301 (stage II).

Once thus positioned:
the probe (200) is driven in rotation on itself by the motorised gearbox (211), using a given control system, at constant speed for example; and
during this rotation, the current consumed by the electric motor in the motorised gearbox (211) is read (stage III).

Once the control current has been read for one or more turns, the probe is unlocked and subjected to an incremental displacement by means of the propulsion shaft (300) or any other equivalent means (stage IV).

Stages II to IV are then repeated, firstly according to the number of increments necessary to cover the width of the spacing plate, and secondly according to the precision that is required in the latter.

After acquisition in all the analysis planes corresponding to these different incremental steps, the computer (213) analyses the different curves of current or power consumption (stage V).

For example, the consumption current or power is compared to the input signal in the case of a spacing plate with no clogging. The comparison can also be done on other calibrated reference signals that are representative of dimensional data (specimen tubes).

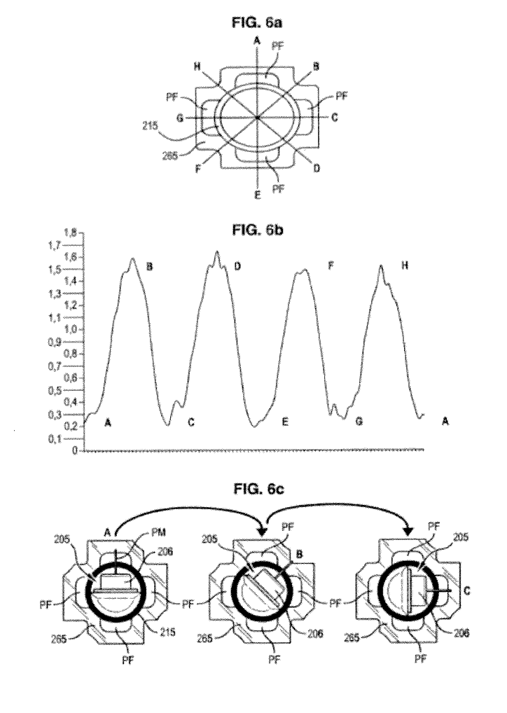

The performance of the rotating magnetic probe in the case in which the foliate passages, PF, at the spacer (265) are not obstructed is illustrated in FIGS. 6a to 6c. When the probe (205) goes from point A to point B, it finds itself attracted by the material present at point B. This attraction is maximum in the middle of the centring sector. Beyond this point, the forces of attraction on the probe decrease (distancing of the material) and reach minimum when the probe (205) arrives at point C (the centre of the foliate passage).

In the same way, the probe (205) will be most attracted at points C, E and G, and reach maximum attraction at points, D, F and H.

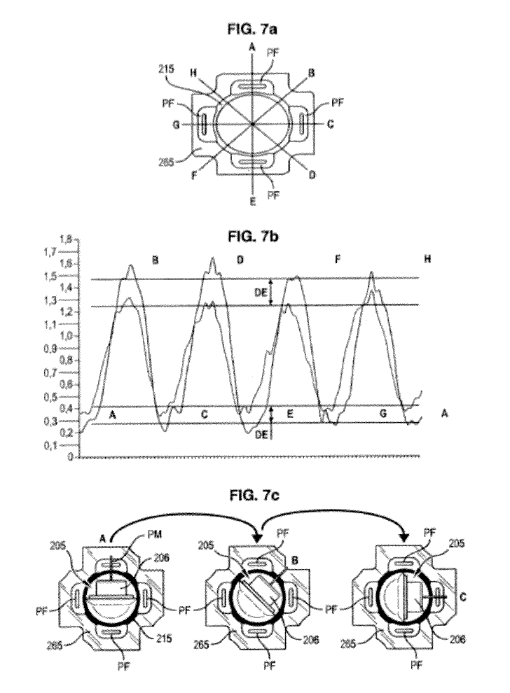

In the case in which the four foliate passages are obstructed (FIGS. 7a to 7c), the attraction remains maximum in the middle of the centring sectors (point B for example), but is lower than in the previous case of a foliate passage that is not obstructed, due to the presence of a deposit in the latter. Beyond this middle point, the forces of attraction decrease and reach minimum when the probe arrives at point C, E or G.

In the case of a foliate passage (PF) that is obstructed, it is observed that the forces of attraction are lower than in the case of a foliate passage that is not obstructed. The forces of attraction depend in fact on the magnetic gap between the permanent magnet and the deposits. When the foliate passages (PF) are not obstructed, the forces of attraction are large at the centring sectors of the tube. On the other hand when the passages are obstructed, there are smaller variations of the magnetic gap and therefore smaller variations in the forces of attraction. The variation of power supplied by the motor is correlated with the volume of the deposits (see double-arrow (DE) in FIG. 7b.

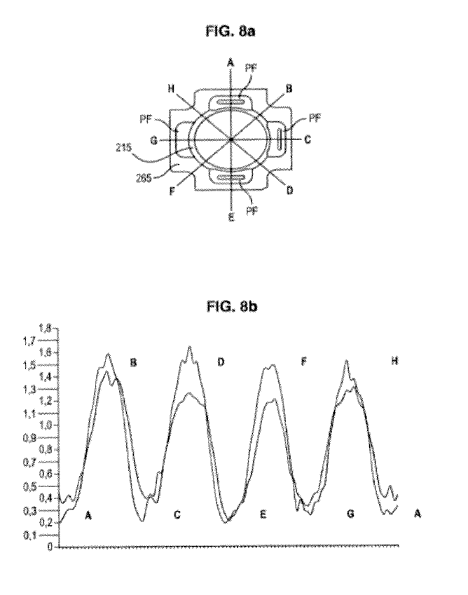

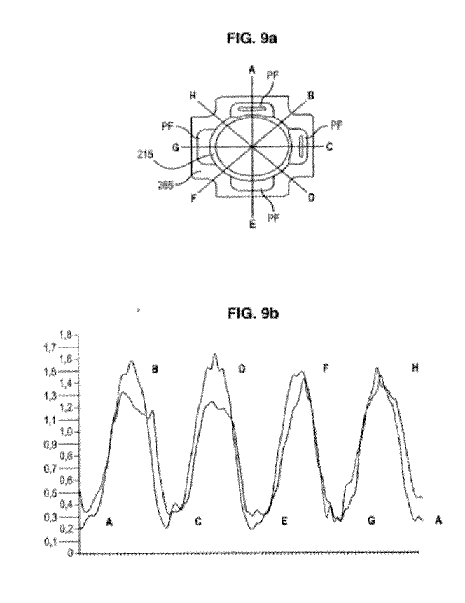

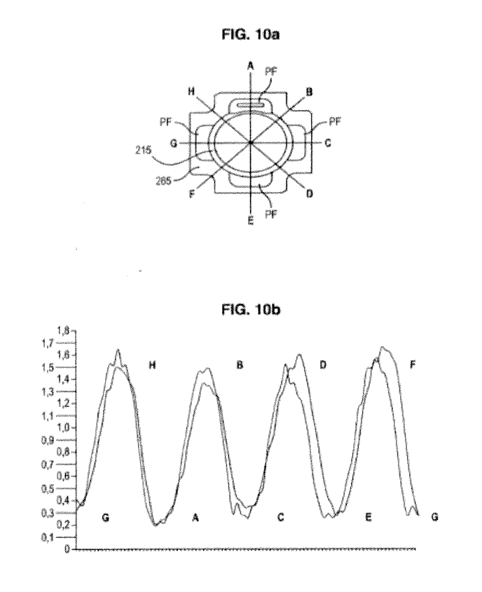

In the same way, in the case of acquisition curves with three, two or just one obstructed foliate passages, the shape of the signals and the corresponding amplitudes before or after the foliate passages allow the presence of clogging in the foliate passages (FIGS. 8a, 8b; 9a, 9b; 10a, 10b) to be detected.

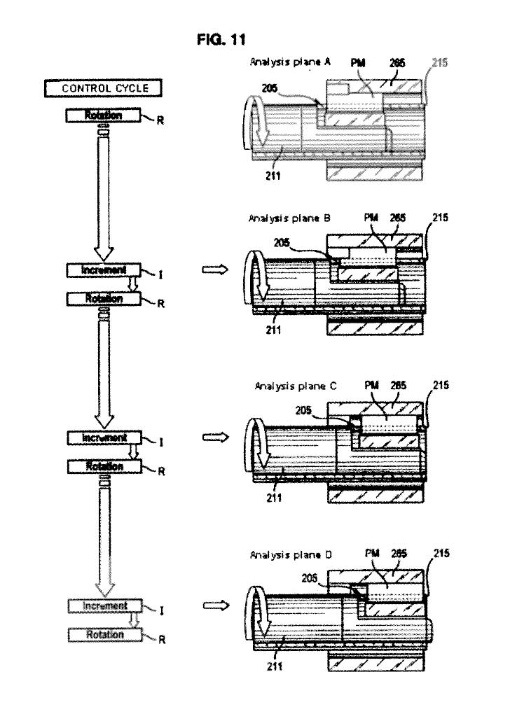

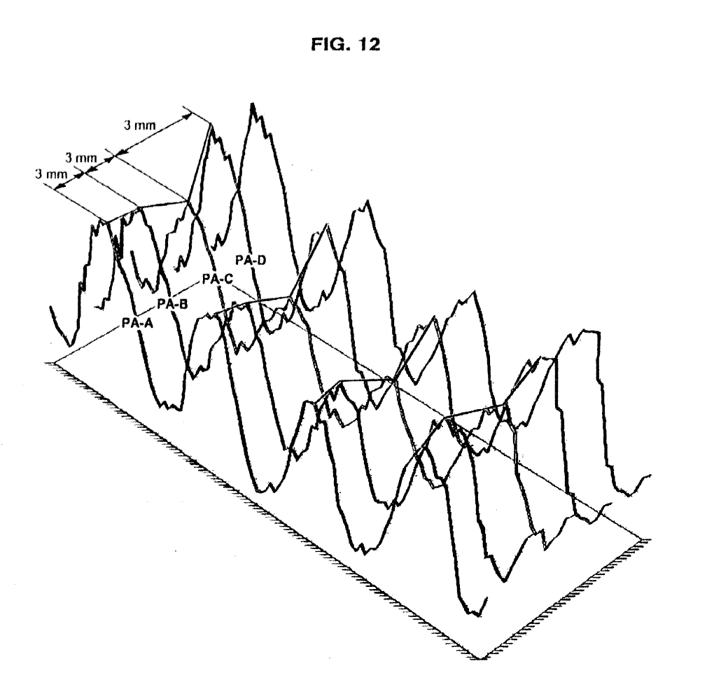

FIG. 11 illustrates the control cycle of the movements imparted to the permanent magnet (206). The said magnet (206) is first positioned at a certain height in relation to the spacer.

It is then driven in rotation on itself for one turn or more (rotation R). Once the signal for the current or power amplitude has been acquired, the longitudinal displacement of the probe (205) in the tube (215) is incremented (increment I), and then it undergoes another rotation R for one complete turn.

As illustrated in FIG. 11, these operations are repeated to scan all the height of the spacer (265).

This results in the acquisition of a succession of curves, which can be converted into a 3D representation for example.

FIG. 12 is such a 3D representation which shows the curves obtained for four analysis planes, PA-A, PA-B, PA-C and PA-D (equidistant by 3 mm).

A fifth curve is added, which acts as a reference curve.

In this FIG. 12 for example, it can be seen that the acquisition effected in the last analysis plane (plane PA-D) is of the same shape as the reference curve—the clogging stops between analysis planes PA-C and PA-D.

In the case illustrated, the depth of clogging is about 7.5 mm. The shape of the curve in the plane of the analysis, PA-C, shows the smaller amplitudes at the peaks, because the thickness at the deposits is greater in this plane.

The algorithm run by the computer (213) executes a comparison with the reference curve, and analyses the amplitudes of the peaks in order to deduce from this the distribution of the deposits and their thickness where appropriate.

By way of example, the magnetic probe can perform a rotation of 450 degrees, and incremental steps of 0.5 to 1 mm.

As it will have been understood, such a solution allows greater precision in detection of the clogging, as well as greater precision regarding the depths at which the deposits are located.

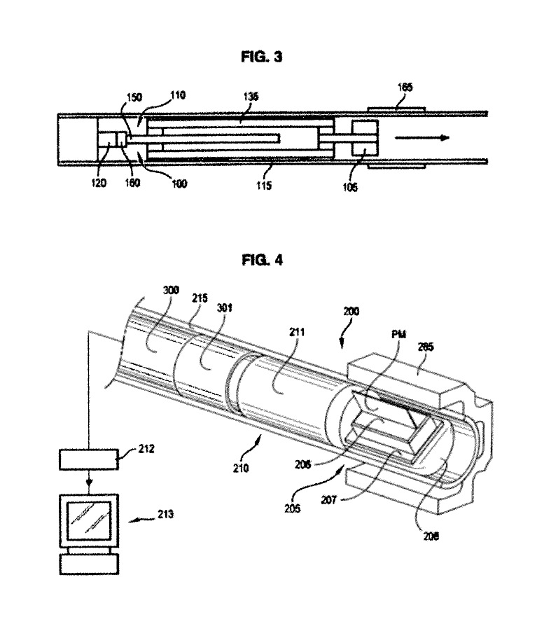

It will also be seen that analysis of the clogging of the spacing plates of a steam generator tube can be accomplished advantageously by using, in a first stage, an axial probe method with a structure of the type described in patent application FR0853200 (structure of FIG. 3—displacement of a magnetised source inside the tube in the direction of its length by means of an electric motor, measurement of the amplitude of current in the electric motor, and determination of the position and/or the thickness and/or the volume of the said deposit, according to variations in the amplitude of the current measured in the electric motor), followed, in a second stage, by a rotating probe method of the type of that has just been described.

1. A method for the detection of fouling or clogging deposits that include at least one ferromagnetic material, such as nickel, magnetite or similar, on or close to the outer wall of a tube, characterised in that it includes at least the following stages:
positioning and locking in altitude of a magnetised source inside the tube,
rotation of the source on itself by driving by means of an electric motor and measuring the amplitude of the current in the said electric motor during this driving in rotation,
analysis of the curve obtained, so as to detect and, where appropriate, to evaluate the clogging.

2. A method according to claim 1, characterised in that after rotation of the source, the latter is moved incrementally in altitude inside the tube and in that, after locking, the previous stages are repeated.

3. A method according to one of the previous claims, characterised in that the magnetised source consists of at least one permanent magnet.

4. A method according to either of claim 1 or 3, characterised in that the rotation of the magnetised source in the tube is a rotation at constant speed.

5. A method according to either of claims 1 to 4, characterised in that the analysis stage includes a stage for comparison of the variation in the magnitude or the power of the current measured in the motor with a reference model and/or a calibrated model.

6. A method according to either of claims 1 to 5, characterised in that a prior axial detection process is performed, which includes at least the following stages:
displacement of a magnetised source inside the tube in the direction of its length by means of an electric motor,
measurement of the amplitude of the current in the electric motor, and
determination of the position and/or the thickness and/or the volume of the said deposit according to variation of the amplitude of the current measured in the electric motor.

7. A device for the detection of fouling or clogging deposits that include at least one ferromagnetic material, such as nickel, magnetite or similar, on or close to the external wall of a tube, characterised in that it includes:
at least one magnetised source,
means capable of positioning and locking the said magnetised source in altitude inside the tube,
means that drive the said magnetised source in rotation inside the said tube and that include an electric motor,
means for measuring the amplitude or the power of the current in the said electric motor during the driving in rotation of the source, and
means for analysing the variations in the amplitude of the current measured in the electric motor.

8. A device according to claim 7, characterised in that it includes means to displace the said probe incrementally inside the tube.

9. A device according to one of claim 7 or 8, characterised in that the magnetised source consists of at least one permanent magnet.

10. A device according to either of claims 7 to 9, characterised in that the driving means cause the magnetised source to turn in the tube in a rotation at constant speed.

11. Application of the method according to any of claims 1 to 6 to the detection of deposits in the quadrifoliate holes of the spacers in a steam generator of a pressurised water nuclear reactor or PWR.
